(19) United States
(12) Patent Application Publication
(10) Pub. No.: US 2025/0172615 A1
(43) Pub. Date: May 29, 2025

(54) IC APPARATUS OF BATTERY MONITORING SYSTEM AND CONTROL METHOD THEREOF

(71) Applicant: HYUNDAI MOBIS CO., LTD., Seoul (KR)

(72) Inventor: Ah Rum HUR, Yongin-si (KR)

(73) Assignee: HYUNDAI MOBIS CO., LTD., Seoul (KR)

(21) Appl. No.: 18/952,111

(22) Filed: Nov. 19, 2024

(30) Foreign Application Priority Data
Nov. 28, 2023 (KR) 10-2023-0167840

(51) Int. Cl. G01R 31/36; G01R 31/3835

(52) U.S. Cl. CPC G01R 31/3648; G01R 31/3835

(57) ABSTRACT

Provided is an IC device of a battery monitoring system, which includes multiple sensing ICs configured to diagnose a state of a battery and a reference IC configured to periodically activate the multiple sensing ICs and transmit battery diagnostic results from each sensing IC to a micom (microcomputer). The multiple sensing ICs and the reference IC are provided in a daisy chain configuration. The reference IC periodically activates the multiple sensing ICs on the daisy chain on behalf of the micom, and also activates the micom when there is an abnormality in the battery.

### CROSS-REFERENCE TO RELATED APPLICATION

This application claims priority from and the benefit of Korean Patent Application No. 10-2023-0167840, filed on Nov. 28, 2023, which is hereby incorporated by reference for all purposes as if set forth herein.

### BACKGROUND

### Field

Exemplary embodiments of the present disclosure relate to an IC device of a battery monitoring system and a control method thereof.

### Discussion of the Background

In general, electric vehicles (e.g., EVs, PHEVs, HEVs) (or eco-friendly cars) are equipped with high-voltage (e.g., 200 V to 400 V) batteries. To sense the voltage of these batteries and monitor their state, a battery monitoring system composed of multiple battery sensing semiconductors (i.e., sensing ICs) is used.

In this case, the battery sensing semiconductors (i.e., sensing ICs) have battery state monitoring functions to verify a state of health (SOH) of a battery and prevent abnormal conditions (e.g., under voltage, thermal runaway).

However, batteries used in eco-friendly vehicles frequently undergo charging and discharging, which may lead to degradation or changes in characteristics. In the related art, when a vehicle is in operation, that is, when the sensing IC and battery are activated, periodic battery state monitoring is possible. However, when the vehicle is parked, that is, when the sensing IC and battery are deactivated, it is difficult to detect battery damage or abnormal conditions. Furthermore, individual diagnostics of the battery state by each sensing IC may lead to collisions in communication frames (i.e., transmission and reception frames) regarding diagnostic results (i.e., sensing results).

Therefore, there is a need for a technology that may periodically activate a deactivated sensing IC on a daisy chain to diagnose a state of the battery, and also allow sensing ICs on the daisy chain to sequentially transmit battery diagnostic results to a micom (microcomputer), thereby avoiding collisions in communication frames.

The related art of the present disclosure is disclosed in Korean Patent No. 10-0198416 (registered on Mar. 2, 1999).

### SUMMARY

Exemplary embodiments of the present disclosure relate to an IC device of a battery monitoring system and a control method thereof that periodically activate a deactivated sensing IC on a daisy chain to diagnose a state of the battery, and also allow sensing ICs on the daisy chain to sequentially transmit battery diagnostic results to a micom (microcomputer), thereby avoiding collisions in communication frames.

In an aspect of the present disclosure, the IC device of a battery monitoring system includes multiple sensing ICs configured to diagnose a state of a battery and a reference IC configured to periodically activate the multiple sensing ICs and transmit battery diagnostic results from each sensing IC to a micom. The multiple sensing ICs and the reference IC are provided in a daisy chain configuration. The reference IC periodically activates the multiple sensing ICs on the daisy chain on behalf of the micom, and also activates the micom when there is an abnormality in the battery.

In an embodiment, the IC device refers to the sensing IC and the reference IC. The IC device includes a direction controller controlling a communication direction on the daisy chain, a protocol controller controlling communication according to a serial communication protocol, a timing controller controlling communication timing, a data transceiver performing transmission and reception of data, a battery abnormality determiner determining a state of a battery, and a diagnostic cycle counter counting an activation cycle of the reference IC and the sensing IC.

In an embodiment, the reference IC activates the diagnostic cycle counter, and the sensing IC deactivates the diagnostic cycle counter.

In an embodiment, the reference IC, based on diagnostic flags from each sensing IC, determines that there is an abnormality in the battery when diagnostic results deviate from a set value, and notifies the micom of the battery abnormality.

In an embodiment, the reference IC is activated upon completion of a diagnostic cycle count by the diagnostic cycle counter and allows each sensing IC to enter an activated state to perform battery diagnostics and receive battery diagnostic results in communication frames.

In an embodiment, the diagnostic cycle counter of the reference IC is activated to perform a diagnostic cycle count, the ICs enter activated mode sequentially from the reference IC to the final sensing IC upon completion of the diagnostic cycle count, the reference IC sequentially transmits a periodic diagnostic trigger to each sensing IC, waits for periodic diagnostic results to be sequentially received from each sensing IC, and determines whether there is an abnormality in the battery based on received diagnostic flags upon receiving periodic diagnostic results. When it is determined that there is an abnormality in the battery, the reference IC notifies the micom of the battery abnormality and continues to remain in IC activated mode. When it is determined that there is no abnormality in the battery, the ICs enter IC deactivated mode sequentially from the final sensing IC to the reference IC.

In an embodiment, the sensing IC is in a waiting state for periodic diagnostics, performs periodic diagnostics upon receiving the periodic diagnostic trigger, transmits periodic diagnostic results to the reference IC, and enters IC deactivated mode. When all ICs from the final sensing IC to the reference IC enter IC deactivated mode, only the diagnostic cycle counter is activated to perform a diagnostic cycle count again.

In another aspect of the present disclosure, the control method of an IC device of a battery monitoring system includes periodically activating, by a reference IC, multiple sensing ICs on a daisy chain on behalf of a micom in the battery monitoring system, where the multiple sensing ICs and the reference IC are provided in the daisy chain configuration. The sensing IC is configured to diagnose a state of a battery, and the reference IC is configured to periodically activate the multiple sensing ICs and transmit battery diagnostic results from each sensing IC to the micom. This control method also includes notifying, by the reference IC, of a battery abnormality by activating the micom when an abnormality is diagnosed in the battery by the sensing IC.

In an embodiment, in the activating of multiple sensing ICs, a diagnostic cycle counter of the reference IC is activated to perform a diagnostic cycle count, and the ICs enter IC activated mode sequentially from the reference IC to the final sensing IC upon completion of the diagnostic cycle count.

In an embodiment, in the notifying of a battery abnormality by activating the micom, the reference IC sequentially transmits a periodic diagnostic trigger to each sensing IC, waits for periodic diagnostic results to be sequentially received from each sensing IC, and determines whether there is an abnormality in the battery based on received diagnostic flags upon receiving periodic diagnostic results. When it is determined that there is an abnormality in the battery, the reference IC notifies the micom of the battery abnormality and continues to remain in IC activated mode. When it is determined that there is no abnormality in the battery, the ICs enter IC deactivated mode sequentially from the final sensing IC to the reference IC.

The embodiments of the present disclosure may periodically activate a deactivated sensing IC on the daisy chain to diagnose a state of the battery, and also allow the sensing ICs on the daisy chain to sequentially transmit battery diagnostic results to the micom, thereby avoiding collisions in communication frames.

### BRIEF DESCRIPTION OF THE DRAWINGS

FIGS. 1A and 1B are illustrative diagrams showing a schematic configuration of a battery monitoring system according to an embodiment of the present disclosure.

FIGS. 2A and 2B are illustrative diagrams showing a schematic configuration of an IC device of a battery monitoring system according to an embodiment of the present disclosure.

FIG. 3 is a flowchart illustrating a control method of an IC device of a battery monitoring system according to an embodiment of the present disclosure.

FIG. 4 is an illustrative diagram illustrating an operation of an IC device when there is no abnormality in a battery as a result of battery monitoring, according to an embodiment of the present disclosure.

FIG. 5 is an illustrative diagram illustrating an operation of an IC device when there is an abnormality in a battery as a result of battery monitoring, according to an embodiment of the present disclosure.

### DETAILED DESCRIPTION OF THE ILLUSTRATED EMBODIMENTS

Hereinafter, embodiments of the present disclosure will be described in detail with reference to the accompanying drawings.

For clarity and convenience in description, thicknesses of lines, sizes of constituent elements, and the like may be illustrated in a non-exact proportion in the drawings. In addition, the terms used below are defined in consideration of the functions thereof in the present disclosure and may vary depending on the intention of a user or an operator or common practice. Therefore, these terms should be contextually defined in light of the present specification.

Hereinafter, exemplary embodiments of the present disclosure will be described in detail with reference to the accompanying drawings so that those skilled in the art may easily practice the present disclosure. However, the present disclosure may be implemented in various different forms and is not limited to the exemplary embodiments provided in the present description. Portions unrelated to the description are omitted to clearly describe the present disclosure, and components that are the same as or similar will be denoted by the same reference numerals throughout the specification.

When one part is referred to as “comprising” (or “including” or “having”) other elements, it should be understood that it can comprise (or include or have) only those elements, or it can comprise (or include or have) other elements as well as those elements unless specifically described otherwise.

Furthermore, an implementation described in this specification may be realized as a method or process, apparatus, software program, data stream or signal, for example. Although the disclosure has been discussed only in the context of a single form of an implementation (e.g., discussed as only a method), an implementation having a discussed characteristic may also be realized in another form (e.g., apparatus or program). The apparatus may be implemented as proper hardware, software or firmware. The method may be implemented in an apparatus, such as a processor commonly referring to a processing device, including a computer, a microprocessor, an integrated circuit or a programmable logic device, for example.

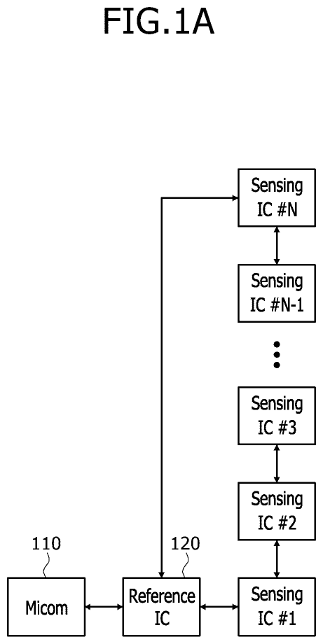

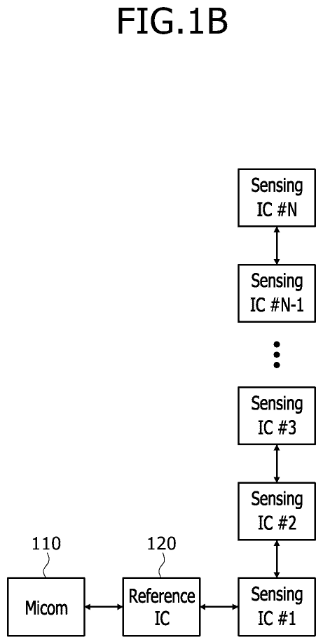

FIGS. 1A and 1B are illustrative diagrams showing a schematic configuration of a battery monitoring system according to an embodiment of the present disclosure.

Referring to FIGS. 1A and 1B, a battery monitoring system according to the embodiment includes multiple sensing ICs (IC#1 to IC#N) for sensing a battery voltage and diagnosing whether there is an abnormality in the battery, and a reference IC 120 that periodically activates the multiple sensing ICs (IC#1 to IC#N) and transmits battery diagnostic results from each sensing IC to a micom (i.e., microcomputer) 110.

In this case, the battery monitoring system, composed of the reference IC 120 and multiple sensing ICs (IC#1 to IC#N), is provided in a daisy chain configuration as shown in FIGS. 1A and 1B.

However, the battery monitoring system according to the embodiment may differ from the conventional battery monitoring system with the daisy chain configuration in that this system further includes the reference IC 120 that leads a diagnostic cycle monitoring operation. The reference IC 120 periodically activates the sensing ICs (IC#1 to IC#N) on the daisy chain on behalf of the micom 110. The reference IC 120 also activates itself and the micom 110, thereby reducing power consumption.

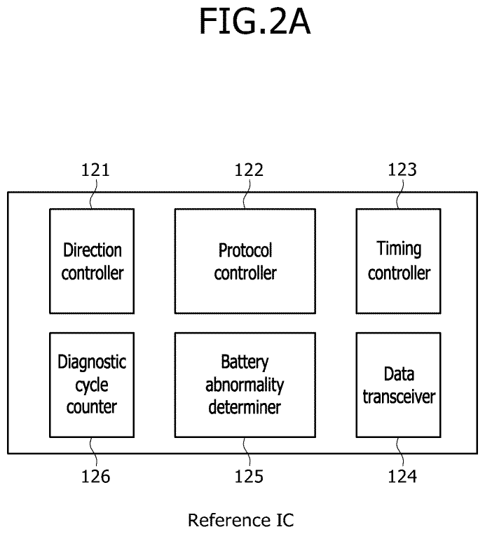

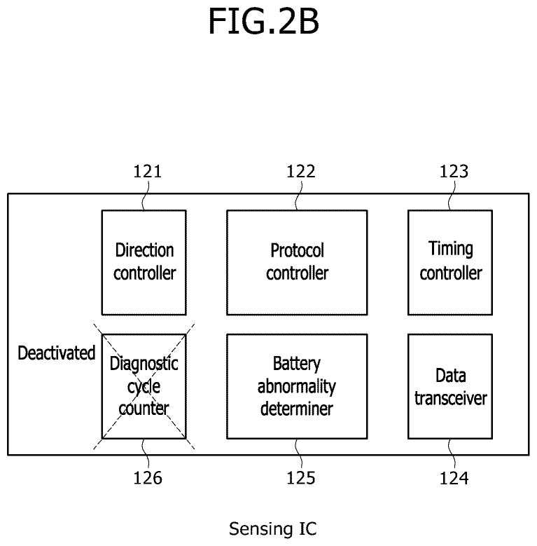

FIGS. 2A and 2B are illustrative diagrams showing a schematic configuration of an IC device of a battery monitoring system according to an embodiment of the present disclosure.

Referring to FIGS. 2A and 2B, a reference IC (see FIG. 2A) and a sensing IC (FIG. 2B) essentially include the same components 121 to 125.

However, a reference IC 120 may further include a diagnostic cycle counter 126 compared to the sensing ICs (IC#1 to IC#N) (in the case of a different configuration) or activate the diagnostic cycle counter 126 (in the case of the same configuration). Conversely, the sensing ICs (IC#1 to IC#N) may not include the diagnostic cycle counter 126 (in the case of a different configuration) or deactivate the diagnostic cycle counter 126 (in the case of the same configuration).

The reference IC 120 leads a diagnostic cycle monitoring operation and periodically activates the sensing ICs (IC#1 to IC#N) on a daisy chain on behalf of a micom 110 (e.g., sequentially activating the sensing ICs on the daisy chain).

In this case, the reference IC 120 activates only the diagnostic cycle counter 126 and then activates the reference IC 120 at a designated cycle.

The sensing ICs (IC#1 to IC#N) are sequentially activated to perform battery diagnostics and transmit battery diagnostic results to a reference IC in communication frames.

The reference IC 120 notifies the micom 110 when diagnostic results deviate from a set value, based on diagnostic flags of each sensing IC (IC#1 to IC#N).

The micom 110 remains deactivated until notified by the reference IC 120 (i.e., notified that battery diagnostic results by each sensing IC deviate from a set value).

Accordingly, the micom 110 remains deactivated, thereby consuming minimal power (i.e., reducing power consumption).

A direction controller 121 controls a communication direction on the daisy chain.

A protocol controller 122 controls communication according to a serial communication protocol.

A timing controller 123 controls communication (transmission and reception) timing (e.g., temporal intervals).

A data transceiver 124 performs the transmission and reception of data.

A battery abnormality determiner 125 determines a battery's state of health (SOH) and abnormal conditions (e.g., under voltage, thermal runaway).

The diagnostic cycle counter 126 counts activation cycles of the reference IC 120 and the sensing ICs (IC#1 to IC#N) for battery diagnostics.

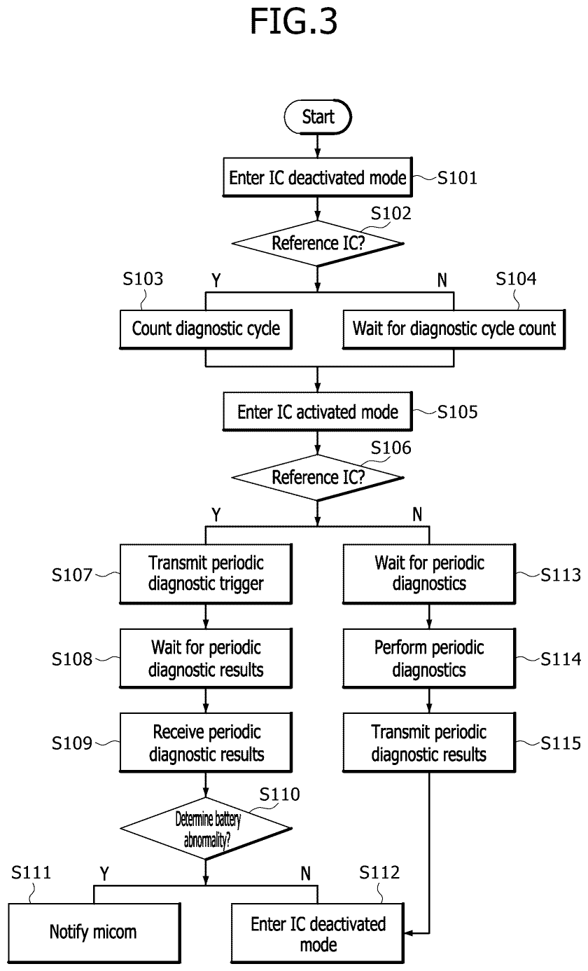

In the embodiment as described above, the reference IC 120 and the sensing ICs (IC#1 to IC#N) may be implemented in the same configuration. However, as illustrated in FIG. 3, an IC device (i.e., integrated circuit) set as the reference IC 120 may perform the role of the reference IC, while another IC device (i.e., integrated circuit), not set as the reference IC 120, may perform the role of the sensing IC.

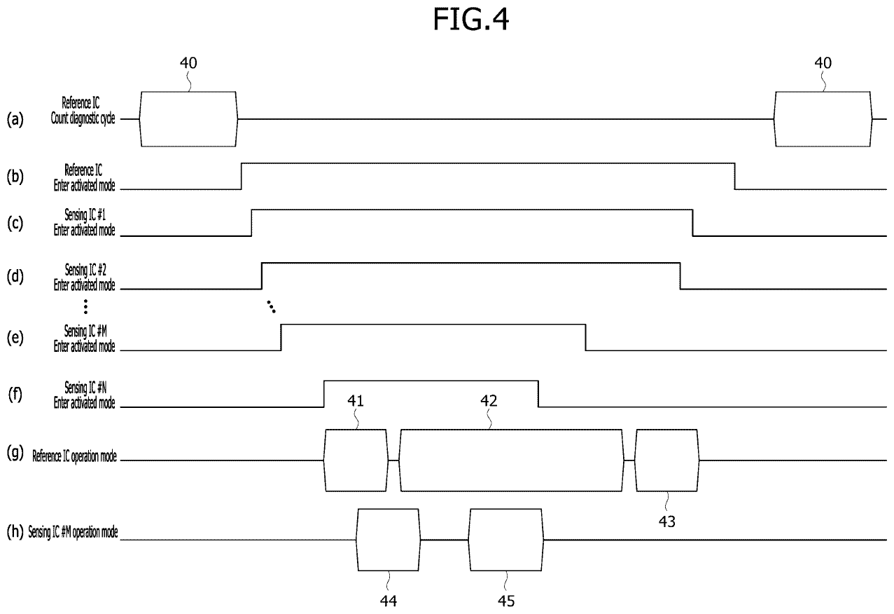

FIG. 3 is a flowchart illustrating a control method of an IC device of a battery monitoring system according to an embodiment of the present disclosure. FIG. 4 is an illustrative diagram illustrating an operation of an IC device (i.e., reference IC and sensing IC) when there is no abnormality in a battery as a result of battery monitoring, according to an embodiment of the present disclosure. The numerical references in FIG. 4 indicate Count diagnostic cycle 40, Reference IC transmits periodic diagnostic trigger 41, Receive periodic diagnostic results of sensing IC#1˜N 42, Reference IC determines periodic diagnostics 43, Receive periodic diagnostic trigger 44, Transmit periodic diagnostic results of sensing IC#M 45.

Referring to FIG. 3, when all IC devices of the battery monitoring system enter deactivated mode (S101), an IC device (i.e., integrated circuit) set as a reference IC 120 (example of S102) activates a diagnostic cycle counter 126 to perform a diagnostic cycle count (S103) (see (a) of FIG. 4).

Another IC device (i.e., sensing IC) that is not set as the reference IC 120 (S102—No) waits to be activated while the diagnostic cycle is counted (S104) (i.e., remains deactivated).

Upon completion of the diagnostic cycle count, the IC device enters IC activated mode (S105).

When entering IC activated mode, the ICs enter activated mode sequentially from the reference IC 120 to the final sensing IC (IC#N) (see (b) to (f) of FIG. 4).

Then the IC device set as the reference IC 120 (i.e., integrated circuit) (example of S106) sequentially transmits a periodic diagnostic trigger to each sensing IC (IC#1 to IC#N) (S107), waits for periodic diagnostic results to be sequentially received from each sensing IC (IC#1 to IC#N) (S108). Upon receiving periodic diagnostic results (S109), the reference IC 120 determines whether there is an abnormality in the battery based on the received diagnostic flags (i.e., determine whether diagnostic results deviate from a set value) (S110) (see (g) of FIG. 4).

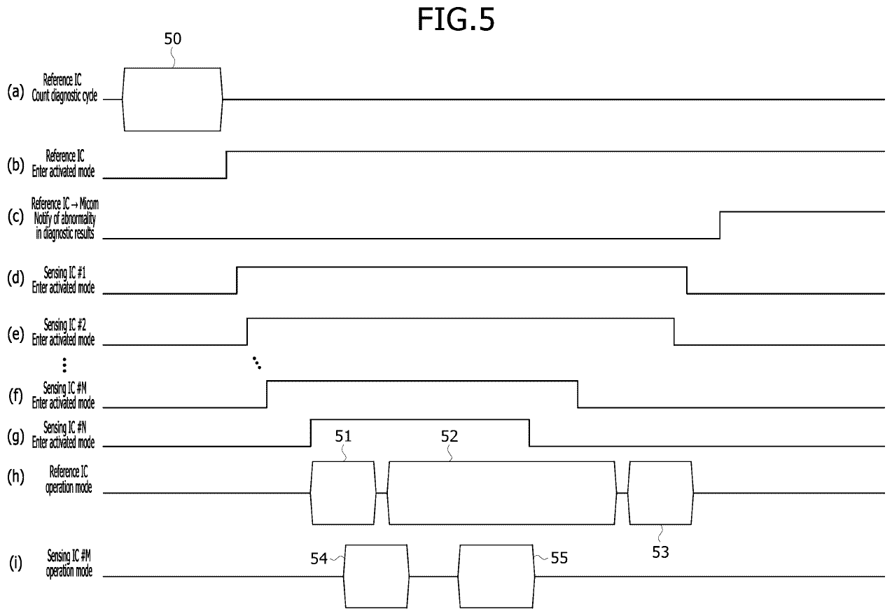

When the reference IC 120 determines that there is an abnormality in the battery (example of S110), the reference IC 120 notifies a micom 110 of the battery abnormality (S111) (see (c) of FIG. 5) and continues to remain in IC activated mode (see (b) of FIG. 5). When the reference IC 120 determines that there is no abnormality in the battery (S110—No), the reference IC 120 enters IC deactivated mode (S112).

When entering IC deactivated mode, the ICs enter deactivated mode sequentially from the final sensing IC (IC#N) to the reference IC 120 (see (f) to (b) of FIG. 4).

On the other hand, the IC device that is not set as the reference IC 120 (i.e., sensing IC) (S106—No) is in a waiting state for periodic diagnostics (S113). Upon receiving the periodic diagnostic trigger, the IC device performs periodic diagnostics (S114), transmits periodic diagnostic results to the reference IC 120 (S115), and then enters IC deactivated mode (S112) (see (h) of FIG. 4).

When all ICs from the final sensing IC (IC#N) to the reference IC 120 enter IC deactivated mode (S101), only the diagnostic cycle counter 126 is activated to perform a diagnostic cycle count (S103) (see (a) of FIG. 4).

FIG. 5 is an illustrative diagram illustrating an operation of an IC device (i.e., reference IC and sensing IC) when there is an abnormality in a battery as a result of battery monitoring, according to an embodiment of the present disclosure. The numerical references in FIG. 5 indicate Count diagnostic cycle 50, Reference IC transmits periodic diagnostic trigger 51, Receive periodic diagnostic results of sensing IC#1˜N 52, Reference IC determines periodic diagnostics 53, Receive periodic diagnostic trigger 54, Transmit periodic diagnostic results of sensing IC#M 55.

Referring to FIG. 5, when all IC devices of the battery monitoring system enter deactivated mode, a diagnostic cycle counter 126 of an IC device set as a reference IC 120 (i.e., integrated circuit) is activated to perform a diagnostic cycle count (see (a) of FIG. 5).

In this case, another IC device that is not set as the reference IC 120 (i.e., sensing IC) waits to be activated while the diagnostic cycle is counted (i.e., remains deactivated).

Upon completion of the diagnostic cycle count, the ICs enter activated mode sequentially from the reference IC 120 to the final sensing IC (IC#N) (see (b), (d) to (g) of FIG. 5).

Then the IC device set as the reference IC 120 (i.e., integrated circuit) sequentially transmits a periodic diagnostic trigger to each sensing IC (IC#1 to IC#N), waits for periodic diagnostic results to be sequentially received from each sensing IC (IC#1 to IC#N). Upon receiving periodic diagnostic results, the reference IC 120 determines whether there is an abnormality in the battery based on the received diagnostic flags (i.e., determine whether diagnostic results deviate from a set value) (see (h) of FIG. 5).

When the reference IC 120 determines that there is an abnormality in the battery, the reference IC 120 notifies a micom 110 of the abnormality in the battery (see (C) of FIG. 5). When there is an abnormality in the battery, the reference IC 120 does not enter deactivated mode (see (b) of FIG. 5) (i.e., the reference IC 120 remains in activated mode).

On the other hand, the IC device that is not set as the reference IC 120 (i.e., sensing IC) is in a waiting state for periodic diagnostics. Upon receiving the periodic diagnostic trigger, the IC device performs periodic diagnostics, transmits periodic diagnostic results to the reference IC 120, and then enters IC deactivated mode (see (i) of FIG. 5).

When entering IC deactivated mode, the ICs enter IC deactivated mode sequentially from the final sensing IC (IC#N) to the reference IC (IC#1) (see (g) to (d) of FIG. 5).

As described above, the IC device of the battery monitoring system and the control method thereof enable reduced power consumption by consuming only the power needed to drive the diagnostic cycle counter 126 before activating periodic diagnostics. The present disclosure also periodically activates a deactivated sensing IC on the daisy chain to diagnose a state of a deactivated battery. Furthermore, the present disclosure allows sensing ICs on the daisy chain to sequentially transmit battery diagnostic results, thereby avoiding collisions in communication frames.

The IC device and the control method thereof also allow the reference IC 120 and the sensing ICs (IC#1 to IC#N) to be built with the same configuration, and to be configured to operate as either the reference IC 120 or the sensing ICs (IC#1 to IC#N).

Although embodiments of the present disclosure have been described with reference to the accompanying drawings, these embodiments are provided for the illustrative purpose. It will be apparent to those skilled in the art that various modifications and equivalent embodiments can be made from these embodiments disclosed herein. Thus, the true technical scope of the disclosure should be defined by the following claims.

What is claimed is:

1. An IC device of a battery monitoring system, the IC device comprising:
multiple sensing ICs configured to diagnose a state of a battery; and
a reference IC configured to periodically activate the multiple sensing ICs and transmit battery diagnostic results from each sensing IC to a microcomputer,
wherein the multiple sensing ICs and the reference IC are provided in a daisy chain configuration, and
the reference IC periodically activates the multiple sensing ICs on the daisy chain on behalf of the microcomputer, and also activates the microcomputer when there is an abnormality in the battery.

2. The IC device of claim 1, wherein
the IC device refers to the sensing IC and the reference IC and comprises:
a direction controller controlling a communication direction on the daisy chain;
a protocol controller controlling communication according to a serial communication protocol;
a timing controller controlling communication timing;
a data transceiver performing transmission and reception of data;
a battery abnormality determiner determining a state of a battery; and
a diagnostic cycle counter counting an activation cycle of the reference IC and the sensing IC.

3. The IC device of claim 2, wherein
the reference IC activates the diagnostic cycle counter, and
the sensing IC deactivates the diagnostic cycle counter.

4. The IC device of claim 2, wherein the reference IC, based on diagnostic flags from each sensing IC, determines that there is an abnormality in the battery when diagnostic results deviate from a set value, and notifies the microcomputer of the battery abnormality.

5. The IC device of claim 2, wherein the reference IC is activated upon completion of a diagnostic cycle count by the diagnostic cycle counter, and allows each sensing IC to enter an activated state to perform battery diagnostics and receive battery diagnostic results in communication frames.

6. The IC device of claim 1, wherein
a diagnostic cycle counter of the reference IC is activated to perform a diagnostic cycle count,
the sensing ICs enter an IC activated mode sequentially from the reference IC to a final sensing IC among the sensing ICs upon completion of the diagnostic cycle count,
the reference IC sequentially transmits a periodic diagnostic trigger to each sensing IC, waits for periodic diagnostic results to be sequentially received from each sensing IC, and determines whether there is the abnormality in the battery based on received diagnostic flags upon receiving the periodic diagnostic results,
when it is determined that there is the abnormality in the battery, the reference IC notifies the microcomputer of the battery abnormality and continues to remain in the IC activated mode, and
when it is determined that there is no abnormality in the battery, the ICs enter an IC deactivated mode sequentially from the final sensing IC to the reference IC.

7. The IC device of claim 6, wherein
the sensing IC is in a waiting state for periodic diagnostics, performs periodic diagnostics upon receiving the periodic diagnostic trigger, transmits periodic diagnostic results to the reference IC, and enters the IC deactivated mode, and
when all ICs from the final sensing IC to the reference IC enter the IC deactivated mode, only a diagnostic cycle counter is activated to perform a diagnostic cycle count again.

8. A control method of an IC device of a battery monitoring system, the control method comprising:
periodically activating, by a reference IC, multiple sensing ICs on a daisy chain on behalf of a microcomputer in the battery monitoring system where the multiple sensing ICs are configured to diagnose a state of a battery and the reference IC, are configured to periodically activate the multiple sensing ICs and transmit battery diagnostic results from each sensing IC to a microcomputer, are provided in the daisy chain; and
notifying, by the reference IC, of a battery abnormality by activating the microcomputer when an abnormality is diagnosed in the battery by the sensing IC.

9. The control method of claim 8, wherein,
in the activating of multiple sensing ICs,
a diagnostic cycle counter of the reference IC is activated to perform a diagnostic cycle count, and
the ICs enter an IC activated mode sequentially from the reference IC to a final sensing IC among the sensing ICs upon completion of the diagnostic cycle count.

10. The control method of claim 8, wherein,
in the notifying of a battery abnormality by activating the microcomputer,
the reference IC sequentially transmits a periodic diagnostic trigger to each sensing IC, waits for periodic diagnostic results to be sequentially received from each sensing IC, and determines whether there is an abnormality in the battery based on received diagnostic flags upon receiving the periodic diagnostic results,
when it is determined that there is the abnormality in the battery, the reference IC notifies the microcomputer of the battery abnormality and continues to remain in an IC activated mode, and
when it is determined that there is no abnormality in the battery, the ICs enter an IC deactivated mode sequentially from a final sensing IC among the sensing ICs to the reference IC.
